(19) United States
(12) Patent Application Publication
(10) Pub. No.: US 2025/0280608 A1
(43) Pub. Date: Sep. 4, 2025

(54) CELLS WITH INTEGRATED PROTECTION DIODES

(71) Applicant: International Business Machines Corporation, Armonk, NY (US)

(72) Inventors: Ryan Kosciolek, Albany, NY (US); Albert M. Chu, Nashua, NH (US); Terence B. Hook, Jericho Center, VT (US); Charles Nicholas Perez, Burlington, VT (US); Jason J. Stuffle, Burlington, VT (US)

(21) Appl. No.: 18/594,167

(22) Filed: Mar. 4, 2024

(51) Int. Cl. H01L 27/02; H01L 23/535; H01L 29/861

(52) U.S. Cl. CPC H10D 89/611; H01L 23/535; H10D 8/00

(57) ABSTRACT

A semiconductor structure comprises at least one bias structure comprising a first diffusion region having a designated doping type, and at least one protection diode comprising a second diffusion region having the designated doping type, wherein the at least one bias structure is connected to the at least one protection diode through at least one contact line.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments of the invention provide techniques for forming cells with integrated protection diodes.

In one embodiment, a semiconductor structure comprises at least one bias structure, and at least one protection diode, wherein the at least one bias structure is connected to the at least one protection diode through at least one contact line.

In another embodiment, a semiconductor structure comprises at least one bias structure comprising a first diffusion region having a designated doping type, and at least one protection diode comprising a second diffusion region having the designated doping type, wherein the at least one bias structure is connected to the at least one protection diode through at least one contact line.

In another embodiment, a cell comprises a substrate comprising a p-type portion and an n-type portion, wherein the n-type portion comprises an n-well. A p-type bias structure comprises a first p-type diffusion region formed in the p-type portion, and a p-type protection diode comprises a second p-type diffusion region formed in the n-well. An n-type bias structure comprises a first n-type diffusion region formed in the n-well, and n-type protection diode comprises a second n-type diffusion region formed in the p-type portion. The p-type bias structure is connected to the p-type protection diode through a first contact line. The n-type bias structure is connected to the n-type protection diode through a second contact line.

These and other features and advantages of embodiments described herein will become more apparent from the accompanying drawings and the following detailed description.

### BRIEF DESCRIPTION OF THE DRAWINGS

FIG. 1A depicts a schematic cross-sectional view of a semiconductor structure including a well tap cell with a p+ diffusion type protection diode, according to an embodiment of the invention.

FIG. 1B depicts a schematic top view of a semiconductor structure including a well tap cell with a p+ diffusion type protection diode, according to an embodiment of the invention.

FIG. 2A depicts a schematic cross-sectional view of a semiconductor structure including a well tap cell with an n+ diffusion type protection diode, according to an embodiment of the invention.

FIG. 2B depicts a schematic top view of a semiconductor structure including a well tap cell with an n+ diffusion type protection diode, according to an embodiment of the invention.

FIG. 3A depicts a schematic cross-sectional view of a semiconductor structure including a well tap cell with a p+ diffusion type protection diode and an n+ diffusion type protection diode, according to an embodiment of the invention.

FIG. 3B depicts a schematic top view of a semiconductor structure including a well tap cell with a p+ diffusion type protection diode and an n+ diffusion type protection diode, according to an embodiment of the invention.

FIG. 4 depicts a schematic top view of a semiconductor structure including multiple well tap cells with p+ diffusion type protection diodes, according to an embodiment of the invention.

FIG. 5A depicts a schematic cross-sectional view of a semiconductor structure including a filler cell with a p+ diffusion type protection diode, according to an embodiment of the invention.

FIG. 5B depicts a schematic top view of a semiconductor structure including a filler cell with a p+ diffusion type protection diode, according to an embodiment of the invention.

### DETAILED DESCRIPTION

Illustrative embodiments of the invention may be described herein in the context of illustrative methods for forming semiconductor structures including well tap cells and filler cells with integrated protection diodes, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Plasma processing may be used in connection with etching and deposition when manufacturing semiconductor devices. However, plasma processing may damage components on a wafer due to, for example, the building up of charges on the semiconductor structure caused by active ions that are present during plasma processing. For example, when a semiconductor wafer is exposed to plasma, current density increases. In more detail, a high electric field develops across a gate and substrate of MOSFET during plasma processing, forcing the unwanted charges through metal lines and gate dielectrics. Moreover, long interconnect lines may further increase the current density by amplifying current density across gate dielectrics. These long interconnect lines may be referred to herein as “antennas.” The area of antenna that is exposed to plasma affects how much charge is collected, with larger areas resulting in larger amounts of charge being collected. For example, a higher ratio of an area of an antenna to an area of a gate dielectric under the gate (referred to herein as “antenna ratio (AR)”) results in larger amounts of charge collection. Larger amounts of charge collection may cause more damage. The damage can include, for example, degradation of gate dielectric layers of, for example, MOSFETs and/or non-volatile memories (NVMs). Plasma charging damage can also degrade insulators of metal-insulator-metal (MIM) capacitors and other semiconductor devices.

Illustrative embodiments provide configurations for protection diodes and bias structures that introduce current drain paths to reduce current density caused by plasma processing. The illustrative embodiments advantageously provide structures for the reduction of potential to reduce and/or prevent device performance degradation.

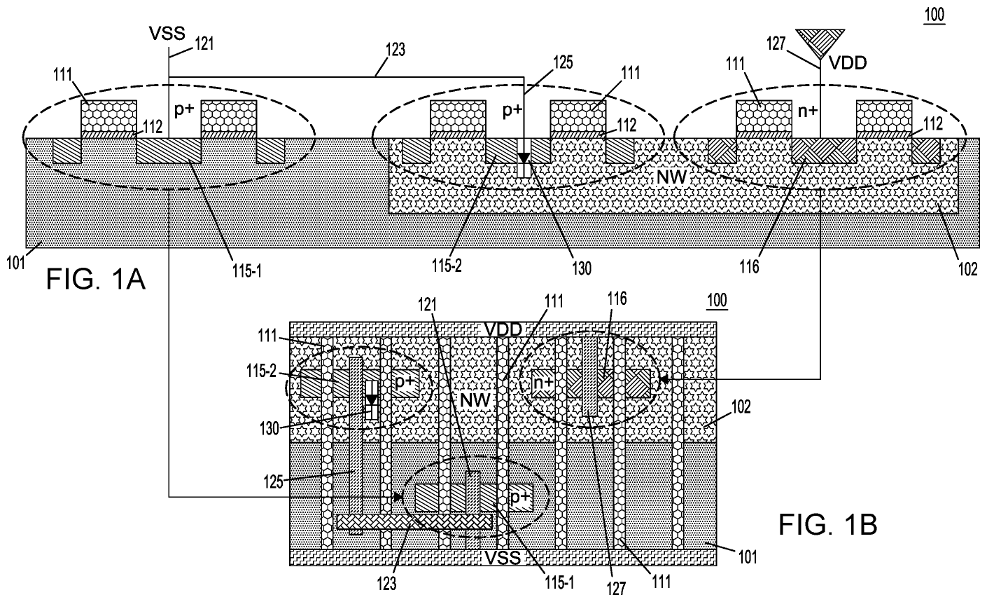

Referring to FIGS. 1A and 1B, a semiconductor structure 100 includes a p-type semiconductor substrate 101 and an n-well (NW) 102 formed in the p-type semiconductor substrate 101. The p-type semiconductor substrate 101 may also be referred to herein as a p-well or p-type portion, and the n-well 102 may also be referred to herein as an n-type portion. The semiconductor structure 100 may also be referred to herein as a well tap cell.

The material of the p-type semiconductor substrate 101 and n-well 102 comprises semiconductor material including, but not limited to, silicon (Si), III-V, II-V compound semiconductor materials or other like semiconductor materials. In addition, multiple layers of the semiconductor materials can be used as the semiconductor material of the p-type semiconductor substrate 101 and n-well 102. In a non-limiting embodiment, the p-type semiconductor substrate 101 is doped with, for example, one or more p-type dopants (e.g., boron (B)), and n-well 102 is doped with, for example, one or more n-type dopants (e.g., arsenic (As) or phosphorous (P)), at concentrations in the general range of 5×10¹⁸/cm³ to 5×10¹⁹/cm³, but the embodiments are not necessarily limited thereto.

In illustrative embodiments, gate structures comprising a gate dielectric layer 112 and a gate conductive portion 111 are formed on portions of the p-type semiconductor substrate 101 and n-well 102. P-type (e.g., p+) diffusion regions 115-1 and 115-2 (collectively p-type diffusion regions 115) are disposed in the p-type semiconductor substrate 101 and n-well 102, respectively, between and/or on lateral sides of the gate structures comprising the gate dielectric layers 112 and the gate conductive portions 111. N-type (e.g., n+) diffusion regions 116 are disposed in the n-well 102 between and/or on lateral sides of gate structures comprising the gate dielectric layers 112 and the gate conductive portions 111. As can be understood, in active devices (e.g., MOSFETs), the p-type diffusion regions 115 and the n-type diffusion regions 116 would be source/drain regions. The semiconductor structure 100 may include other elements for a planar FET, such as for example, channel regions under the gate dielectric layers 112 and gate spacers on the lateral sides of the gate structures and shallow trench isolation (STI) regions in the p-type semiconductor substrate 101 and/or n-well 102.

The gate dielectric layers 112 are formed between bottom surfaces of respective gate conductive portions 111 and top surface portions of the p-type semiconductor substrate 101 and of n-well 102 corresponding to where channel regions would be located. A gate dielectric layer 112 includes, for example, a high-K dielectric layer including, but not necessarily limited to, HfO₂ (hafnium oxide), ZrO₂ (zirconium dioxide), hafnium zirconium oxide, Al₂O₃ (aluminum oxide), and Ta₂O₅ (tantalum V oxide) or another electronic grade (EG) oxide. Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. According to an embodiment, a gate conductive portion 111 includes a work-function metal (WFM) layer, including but not necessarily limited to, for a p-type FET (PFET), titanium nitride (TiN), tantalum nitride (TaN) or ruthenium (Ru), and for an n-type FET (NFET), TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on a gate dielectric layer 112. The gate conductive portion 111 can further include a gate layer including, but not necessarily limited to, polysilicon or metals, such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the gate dielectric layer 112. Alternatively, the gate conductive portion 111 includes one of the WFM layer and the gate layer.

In one or more embodiments of the invention, the layers for the gate dielectric layer 112 and gate conductive portion 111 can be deposited using, for example, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD), sputtering, and/or plating, followed by one or more planarization processes, such as, chemical mechanical planarization (CMP).

The p-type diffusion regions 115 comprise, for example, semiconductor materials of the p-type semiconductor substrate 101 and of the n-well 102 doped with p-type dopants including, for example, boron (B), boron fluoride (BF₂), gallium (Ga), indium (In), and thallium (Tl) at a concentration of about 1×10¹⁹/cm³ to about 3×10²¹/cm³. The n-type diffusion regions 116 comprise, for example, semiconductor materials of the n-well 102 doped with n-type dopants including, for example, phosphorus (P), arsenic (As) and antimony (Sb) at a concentration of about 1×10¹⁹/cm³ to about 3×10²¹/cm³.

The semiconductor structure 100 includes a p-type bias structure comprising a p-type diffusion region 115-1 formed in the p-type semiconductor substrate 101 between two gate structures and connected to a source voltage (VSS) (also referred to herein as “a ground voltage”) through a first contact line 121. In more detail, the first contact line 121 connects VSS to the p-type diffusion region 115-1 by contacting a top surface of the p-type diffusion region 115-1 between the two gate structures. As can be seen in the schematic cross-sectional view of FIG. 1A, the first contact line 121 extends perpendicular to a top surface of the p-type semiconductor substrate 101. A second contact line 123 (e.g., cross-contact line) connects the first contact line 121 to a third contact line 125. As can be seen in the schematic cross-sectional view of FIG. 1A, the second contact line 123 extends parallel to a top surface of the p-type semiconductor substrate 101 and of the n-well 102, and the third contact line 125 extends perpendicular to a top surface of the n-well 102 to contact a top surface of a p-type diffusion region 115-2, which is disposed between two gate structures on the n-well 102.

A protection diode 130 comprising the p-type diffusion region 115-2 is formed in the n-well 102. The protection diode 130 is a p+ diffusion type protection diode. The p-type bias structure comprising the p-type diffusion region 115-1 formed in the p-type semiconductor substrate 101 is connected to the protection diode 130 through the first, second and third contact lines 121, 123 and 125. As can be understood, the p-type diffusion region 115-1 of the bias structure in the p-type semiconductor substrate is connected to the p-type diffusion region 115-2 of the protection diode 130 in the n-well 102. In illustrative embodiments, the protection diode 130 comprises a plasma charge protection diode, and is a reverse bias diode. The protection diode 130 is in a reverse bias configuration when an external voltage applied across the protection diode 130 results in a positive terminal being connected to an n-side of the protection diode 130 and a negative terminal being connected to a p-side of the protection diode 130.

The semiconductor structure 100 includes an n-type bias structure comprising an n-type diffusion region 116 formed in the n-well 102 between two gate structures and connected to a power voltage (VDD) (also referred to herein as a “drain voltage”) through a fourth contact line 127. In more detail, the fourth contact line 127 connects VDD to the n-type diffusion region 116 by contacting a top surface of the n-type diffusion region 116 between the two gate structures. As can be seen in the schematic cross-sectional view of FIG. 1A, the fourth contact line 127 extends perpendicular to a top surface of the n-well 102.

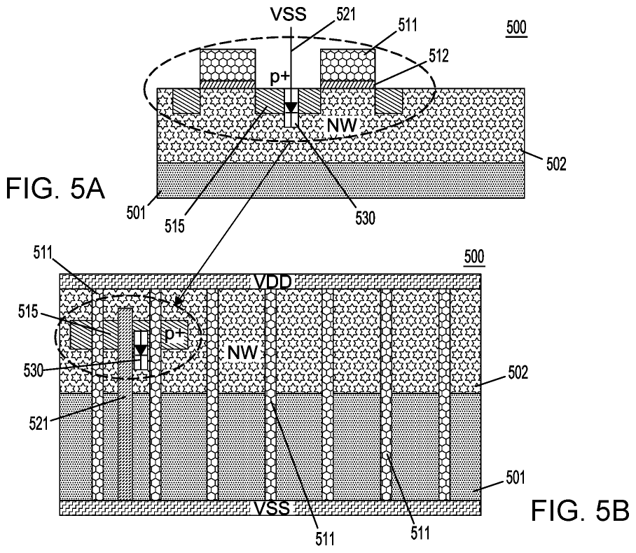

The p-type bias structure connects (taps) VSS to the p-type diffusion region 115-1 in the p-type semiconductor substrate 101 and the n-type bias structure connects (taps) VDD to the n-type diffusion region 116 in the n-well 102. The p-type bias structure biases the p-type semiconductor substrate 101 to a certain voltage relative to VSS, and the n-type bias structure biases the n-well 102 to a certain voltage relative to VDD. The biasing prevents latch-up and avoids body effects. The applied bias can be offset from VDD and VSS to, for example, adjust the threshold voltage of the device. Biasing the p-type semiconductor substrate 101 and the n-well 102 is a function of a well tap cell. The bias structures described herein form a discharge path in conjunction with the protection diodes. In the case of a protection diode being integrated into a cell other than a well tap cell such as, for example, a filler cell or edge cell, as described in more detail in connection with FIGS. 5A and 5B, the bias structure can be omitted.

In illustrative embodiments, one or more layers of dielectric material are deposited on the semiconductor structure 100 including the gate structures, the p-type diffusion regions 115 and the n-type diffusion regions 116 to form one or more inter-layer dielectric (ILD) layers. In forming the first, second, third and fourth contact lines 121, 123, 125 and 127, respective trenches corresponding to the first, second, third and fourth contact lines 121, 123, 125 and 127 are formed in the one or more ILD layers. One or more layers of liner material are deposited to line side and bottom surfaces of the respective trenches with a liner (e.g., diffusion barrier layer and/or seed layer). A layer of metallic material is deposited on the liner to fill remaining portions of the respective trenches for each of the first, second, third and fourth contact lines 121, 123, 125 and 127. The surface of the semiconductor structure 100 is planarized down to the upper surface of the one or more ILD layers to remove excess liner and metallic material of the deposited layers, resulting in the first, second, third and fourth contact lines 121, 123, 125 and 127. In one or more embodiments, the liner may be formed of one or more conformal layers of metallic material such as a titanium (Ti) and/or titanium nitride (TiN). In one or more embodiments, the metallic fill material comprises, for example, copper, tungsten, cobalt, ruthenium, etc.

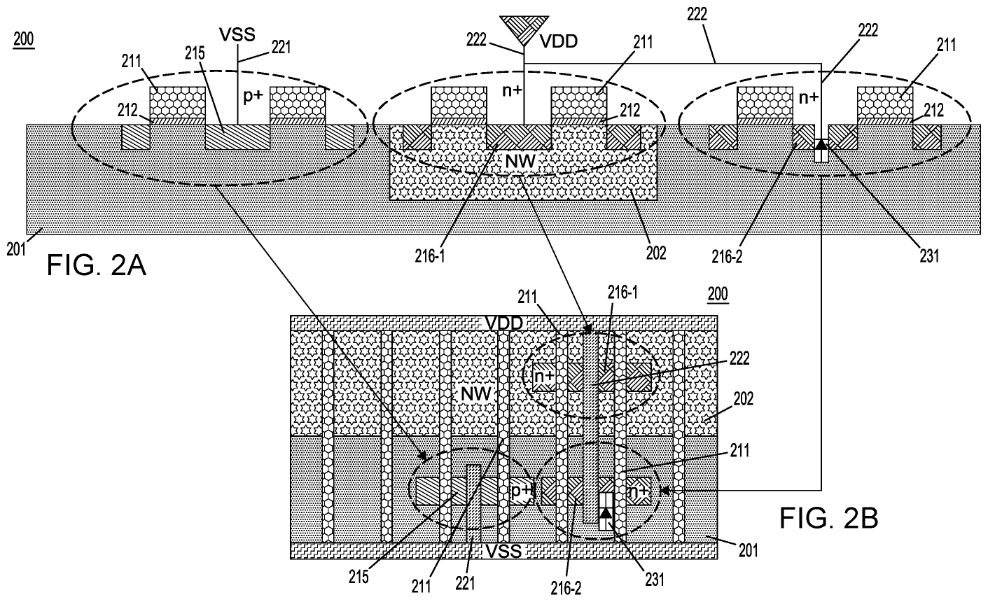

Referring to FIGS. 2A and 2B, a semiconductor structure 200 includes a p-type semiconductor substrate 201 and an n-well 202 formed in the p-type semiconductor substrate 201. The p-type semiconductor substrate 201 may also be referred to herein as a p-well or p-type portion, and the n-well 202 may also be referred to herein as an n-type portion. The semiconductor structure 200 may also be referred to herein as a well tap cell.

The material of the p-type semiconductor substrate 201 and n-well 202 comprises the same semiconductor material as or similar semiconductor material to that of the p-type semiconductor substrate 101 and n-well 102. In illustrative embodiments, the p-type semiconductor substrate 201 and n-well 202 have the same doping configuration as or a similar doping configuration to that of the p-type semiconductor substrate 101 and n-well 102.

In illustrative embodiments, gate structures comprising a gate dielectric layer 212 and a gate conductive portion 211 are formed on portions of the p-type semiconductor substrate 201 and n-well 202. The gate structures of the semiconductor structure 200 comprise the same structure as or a similar structure to the gate structures of the p-type semiconductor substrate 101 and n-well 102.

A p-type (e.g., p+) diffusion region 215 is disposed in the p-type semiconductor substrate 201 between and/or on lateral sides of the gate structures comprising the gate dielectric layers 212 and the gate conductive portions 211. N-type (e.g., n+) diffusion regions 216-1 and 216-2 (collectively n-type diffusion regions 216) are disposed in the n-well 202 and in the p-type semiconductor substrate 201, respectively, between and/or on lateral sides of gate structures comprising the gate dielectric layers 212 and the gate conductive portions 211. As can be understood, in active devices (e.g., MOSFETs), the p-type diffusion region 215 and the n-type diffusion regions 216 would be source/drain regions. Like the semiconductor structure 100, the semiconductor structure 200 may include other elements for a planar FET, such as for example, channel regions under the gate dielectric layers 212 and gate spacers on the lateral sides of the gate structures and STI regions in the p-type semiconductor substrate 201 and/or n-well 202.

The gate dielectric layers 212 are formed between bottom surfaces of respective gate conductive portions 211 and top surface portions of the p-type semiconductor substrate 201 and of n-well 202 corresponding to where channel regions would be located. The gate dielectric layers 212 and gate conductive portions 211 include the same materials and configuration as or similar materials and configuration to those of the gate dielectric layers 112 and the gate conductive portions 111.

In one or more embodiments of the invention, the gate dielectric layers 212 and gate conductive portions 211 can be deposited using the same or similar techniques as those used for the gate dielectric layers 112 and gate conductive portions 111.

The p-type diffusion region 215 comprises, for example, a semiconductor material of the p-type semiconductor substrate 201 doped with p-type dopants at a concentration similar to those noted herein above in connection with the p-type diffusion regions 115. The n-type diffusion regions 216 comprise, for example, semiconductor materials of the p-type semiconductor substrate 201 and of the n-well 202 doped with n-type dopants at a concentration similar to those noted herein above in connection with the n-type diffusion regions 116.

Referring to FIGS. 2A and 2B, the semiconductor structure 200 includes a p-type bias structure comprising the p-type diffusion region 215 formed in the p-type semiconductor substrate 201 between two gate structures and connected to a source voltage (VSS) through a first contact line 221. Referring to FIGS. 2A and 2B, the semiconductor structure 200 includes an n-type bias structure comprising an n-type diffusion region 216-1 formed in the n-well 202 between two gate structures and connected to a power voltage (VDD) through a second contact line 222. In more detail, the first contact line 221 connects VSS to the p-type diffusion region 215 by contacting a top surface of the p-type diffusion region 215 between two gate structures. Similarly, a portion of the second contact line 222 connects VDD to the n-type diffusion region 216-1 by contacting a top surface of the n-type diffusion region 216-1 between two gate structures. A second portion of the second contact line 222 extends across the n-well 202 and the p-type semiconductor substrate 201 to an area over the n-type diffusion region 216-2, where a third portion of the second contact line 222 extends down from the second portion of the second contact line 222 to contact a top surface of the n-type diffusion region 216-2 between two gate structures. As can be seen in the schematic cross-sectional view of FIG. 2A, the first and third portions of the second contact line 222 extend perpendicular to a top surface of the n-well 202 and to a top surface of the p-type semiconductor substrate 201, and the second portion of the second contact line 222 extends parallel to a top surface of the p-type semiconductor substrate 201 and of the n-well 202.

A protection diode 231 comprising the n-type diffusion region 216-2 is formed in the p-type semiconductor substrate 201. The protection diode 231 is an n+ diffusion type protection diode. The n-type bias structure comprising the n-type diffusion region 216-1 formed in the n-well 202 is connected to the protection diode 231 through the first, second and third portions of the second contact line 222. As can be understood, the n-type diffusion region 216-1 of the bias structure in the n-well 202 is connected to the n-type diffusion region 216-2 of the protection diode 231 in the p-type semiconductor substrate 201. In illustrative embodiments, the protection diode 231 comprises a plasma charge protection diode, and is a reverse bias diode. The protection diode 231 is in a reverse bias configuration when an external voltage applied across the protection diode 231 results in a positive terminal being connected to an n-side of the protection diode 231 and a negative terminal being connected to a p-side of the protection diode 231.

The p-type bias structure connects (taps) VSS to the p-type diffusion region 215 in the p-type semiconductor substrate 201 and the n-type bias structure connects (taps) VDD to the n-type diffusion region 216-1 in the n-well 202. The p-type bias structure biases the p-type semiconductor substrate 201 to a certain voltage relative to VSS, and the n-type bias structure biases the n-well 202 to a certain voltage relative to VDD. The biasing prevents latch-up and avoids body effects. The applied bias can be offset from VDD and VSS to, for example, adjust the threshold voltage of the device. Biasing the p-type semiconductor substrate 201 and the n-well 202 is a function of a well tap cell. The bias structures described herein form a discharge path in conjunction with the protection diodes.

In illustrative embodiments, one or more layers of dielectric material are deposited on the semiconductor structure 200 including the gate structures, the p-type diffusion region 215 and the n-type diffusion regions 216 to form one or more ILD layers. In forming the first and second contact lines 221 and 222, respective trenches corresponding to the first and second contact lines 221 and 222 are formed in the one or more ILD layers. One or more layers of liner material are deposited to line side and bottom surfaces of the respective trenches with a liner (e.g., diffusion barrier layer and/or seed layer). A layer of metallic material is deposited on the liner to fill remaining portions of the respective trenches for each of the first and second contact lines 221 and 222. The surface of the semiconductor structure 200 is planarized down to the upper surface of the one or more ILD layers to remove excess liner and metallic material of the deposited layers, resulting in the first and second contact lines 221 and 222. In one or more embodiments, the liner and metallic fill material may be formed of the same materials as or similar materials to those of the first, second, third and fourth contact lines 121, 123, 125 and 127 of the semiconductor structure 100.

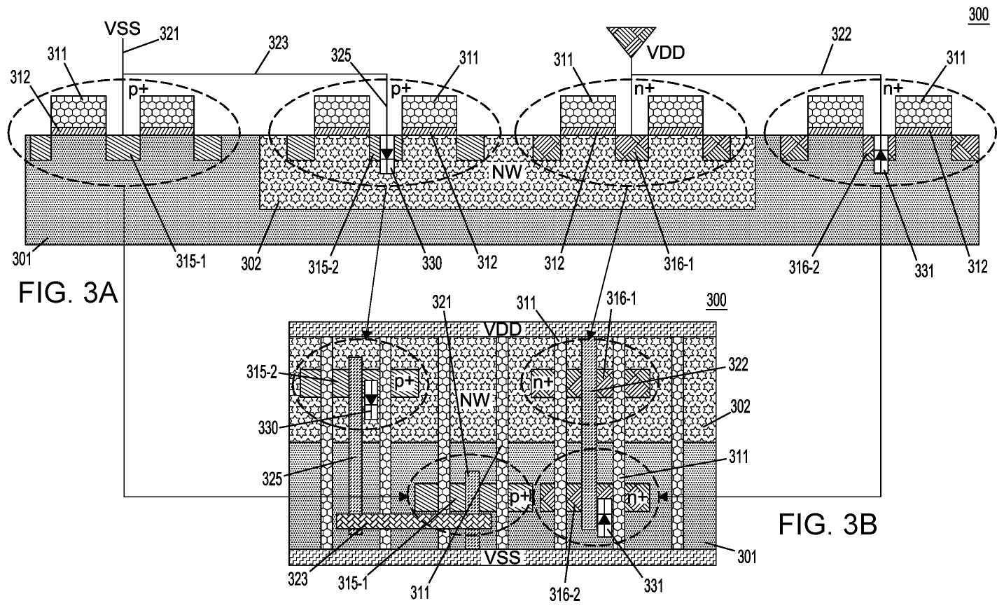

Referring to FIGS. 3A and 3B, the semiconductor structure 300 is essentially a combination of the semiconductor structures 100 and 200. In more detail, the semiconductor structure 300 includes a p-type semiconductor substrate 301 and an n-well 302 formed in the p-type semiconductor substrate 301. The p-type semiconductor substrate 301 may also be referred to herein as a p-well or p-type portion, and the n-well 302 may also be referred to herein as an n-type portion. The semiconductor structure 300 may also be referred to herein as a well tap cell.

The material of the p-type semiconductor substrate 301 and n-well 302 comprises the same semiconductor material as or similar semiconductor material to that of the p-type semiconductor substrates 101/201 and n-wells 102/202. In illustrative embodiments, the p-type semiconductor substrate 301 and n-well 302 have the same doping configuration as or a similar doping configuration to that of the p-type semiconductor substrates 101/201 and n-wells 102/202.

In illustrative embodiments, gate structures comprising a gate dielectric layer 312 and a gate conductive portion 311 are formed on portions of the p-type semiconductor substrate 301 and n-well 302. The gate structures of the semiconductor structure 300 comprise the same structure as or a similar structure to the gate structures of the p-type semiconductor substrates 102/201 and n-wells 102/202.

P-type (e.g., p+) diffusion regions 315-1 and 315-2 (collectively p-type diffusion regions 315) are disposed in the p-type semiconductor substrate 301 and n-well 302, respectively, between and/or on lateral sides of the gate structures comprising the gate dielectric layers 312 and the gate conductive portions 311. N-type (e.g., n+) diffusion regions 316-1 and 316-2 (collectively n-type diffusion regions 316) are disposed in the n-well 302 and in the p-type semiconductor substrate 301, respectively, between and/or on lateral sides of gate structures comprising the gate dielectric layers 312 and the gate conductive portions 311. As can be understood, in active devices (e.g., MOSFETs), the p-type diffusion regions 315 and the n-type diffusion regions 316 would be source/drain regions. Like the semiconductor structures 100/200, the semiconductor structure 300 may include other elements for a planar FET, such as for example, channel regions under the gate dielectric layers 312 and gate spacers on the lateral sides of the gate structures and STI regions in the p-type semiconductor substrate 301 and/or n-well 302.

The gate dielectric layers 312 are formed between bottom surfaces of respective gate conductive portions 311 and top surface portions of the p-type semiconductor substrate 301 and of n-well 302 corresponding to where channel regions would be located. The gate dielectric layers 312 and gate conductive portions 311 include the same materials and configuration as or similar materials and configuration to those of the gate dielectric layers 112/212 and the gate conductive portions 111/211.

In one or more embodiments of the invention, the gate dielectric layers 312 and gate conductive portions 311 can be deposited using the same or similar techniques as those used for the gate dielectric layers 112/212 and gate conductive portions 111/211.

The p-type diffusion regions 315 comprise, for example, semiconductor materials of the p-type semiconductor substrate 301 and of the n-well 302 doped with p-type dopants at a concentration similar to those noted herein above in connection with the p-type diffusion regions 115/215. The n-type diffusion regions 316 comprise, for example, semiconductor materials of the p-type semiconductor substrate 301 and of the n-well 302 doped with n-type dopants at a concentration similar to those noted herein above in connection with the n-type diffusion regions 116/216.

The semiconductor structure 300 includes a p-type bias structure comprising a p-type diffusion region 315-1 formed in the p-type semiconductor substrate 301 between two gate structures and connected to a source voltage (VSS) through a first contact line 321. In more detail, the first contact line 321 connects VSS to the p-type diffusion region 315-1 by contacting a top surface of the p-type diffusion region 315-1 between the two gate structures. As can be seen in the schematic cross-sectional view of FIG. 3A, the first contact line 321 extends perpendicular to a top surface of the p-type semiconductor substrate 301. A second contact line 323 (e.g., cross-contact line) connects the first contact line 321 to a third contact line 325. As can be seen in the schematic cross-sectional view of FIG. 3A, the second contact line 323 extends parallel to a top surface of the p-type semiconductor substrate 301 and of the n-well 302, and the third contact line 325 extends perpendicular to a top surface of the n-well 302 to contact a top surface of a p-type diffusion region 315-2, which is disposed between two gate structures on the n-well 302.

A protection diode 330 comprising the p-type diffusion region 315-2 is formed in the n-well 302. The protection diode 330 is a p+ diffusion type protection diode. The p-type bias structure comprising the p-type diffusion region 315-1 formed in the p-type semiconductor substrate 301 is connected to the protection diode 330 through the first, second and third contact lines 321, 323 and 325. As can be understood, the p-type diffusion region 315-1 of the bias structure in the p-type semiconductor substrate 301 is connected to the p-type diffusion region 315-2 of the protection diode 330 in the n-well 302. In illustrative embodiments, the protection diode 330 comprises a plasma charge protection diode, and is a reverse bias diode. The protection diode 330 is in a reverse bias configuration when an external voltage applied across the protection diode 330 results in a positive terminal being connected to an n-side of the protection diode 330 and a negative terminal being connected to a p-side of the protection diode 330.

The semiconductor structure 300 includes an n-type bias structure comprising an n-type diffusion region 316-1 formed in the n-well 302 between two gate structures and connected to a power voltage (VDD) through a fourth contact line 322. A portion of the fourth contact line 322 connects VDD to the n-type diffusion region 316-1 by contacting a top surface of the n-type diffusion region 316-1 between two gate structures. A second portion of the fourth contact line 322 extends across the n-well 302 and the p-type semiconductor substrate 301 to an area over the n-type diffusion region 316-2, where a third portion of the fourth contact line 322 extends down from the second portion of the fourth contact line 322 to contact a top surface of the n-type diffusion region 316-2 between two gate structures. As can be seen in the schematic cross-sectional view of FIG. 3A, the first and third portions of the fourth contact line 322 extend perpendicular to a top surface of the n-well 302 and to a top surface of the p-type semiconductor substrate 301, and the second portion of the fourth contact line 322 extends parallel to a top surface of the p-type semiconductor substrate 301 and of the n-well 302.

A protection diode 331 comprising the n-type diffusion region 316-2 is formed in the p-type semiconductor substrate 301. The protection diode 331 is an n+ diffusion type protection diode. The n-type bias structure comprising the n-type diffusion region 316-1 formed in the n-well 302 is connected to the protection diode 331 through the first, second and third portions of the fourth contact line 322. As can be understood, the n-type diffusion region 316-1 of the bias structure in the n-well 302 is connected to the n-type diffusion region 316-2 of the protection diode 331 in the p-type semiconductor substrate 301. In illustrative embodiments, the protection diode 331 comprises a plasma charge protection diode, and is a reverse bias diode. The protection diode 331 is in a reverse bias configuration when an external voltage applied across the protection diode 331 results in a positive terminal being connected to an n-side of the protection diode 331 and a negative terminal being connected to a p-side of the protection diode 331.

The p-type bias structure connects (taps) VSS to the p-type diffusion region 315-1 in the p-type semiconductor substrate 301 and the n-type bias structure connects (taps) VDD to the n-type diffusion region 316-1 in the n-well 302. The p-type bias structure biases the p-type semiconductor substrate 301 to a certain voltage relative to VSS, and the n-type bias structure biases the n-well 302 to a certain voltage relative to VDD. The biasing prevents latch-up and avoids body effects. The applied bias can be offset from VDD and VSS to, for example, adjust the threshold voltage of the device. Biasing the p-type semiconductor substrate 301 and the n-well 302 is a function of a well tap cell. The bias structures described herein form a discharge path in conjunction with the protection diodes.

In illustrative embodiments, one or more layers of dielectric material are deposited on the semiconductor structure 300 including the gate structures, the p-type diffusion regions 315 and the n-type diffusion regions 316 to form one or more ILD layers. In forming the first, second, third and fourth contact lines 321, 323, 325 and 322, respective trenches corresponding to the first, second, third and fourth contact lines 321, 323, 325 and 322 are formed in the one or more ILD layers. One or more layers of liner material are deposited to line side and bottom surfaces of the respective trenches with a liner (e.g., diffusion barrier layer and/or seed layer). A layer of metallic material is deposited on the liner to fill remaining portions of the respective trenches for each of the first, second, third and fourth contact lines 321, 323, 325 and 322. The surface of the semiconductor structure 300 is planarized down to the upper surface of the one or more ILD layers to remove excess liner and metallic material of the deposited layers, resulting in the first, second, third and fourth contact lines 321, 323, 325 and 322. In one or more embodiments, the liner and metallic fill material may be formed of the same materials as or similar materials to those of the first, second, third and fourth contact lines 121, 123, 125 and 127 of the semiconductor structure 100 and/or the first and second contact lines 221 and 222 of the semiconductor structure 200.

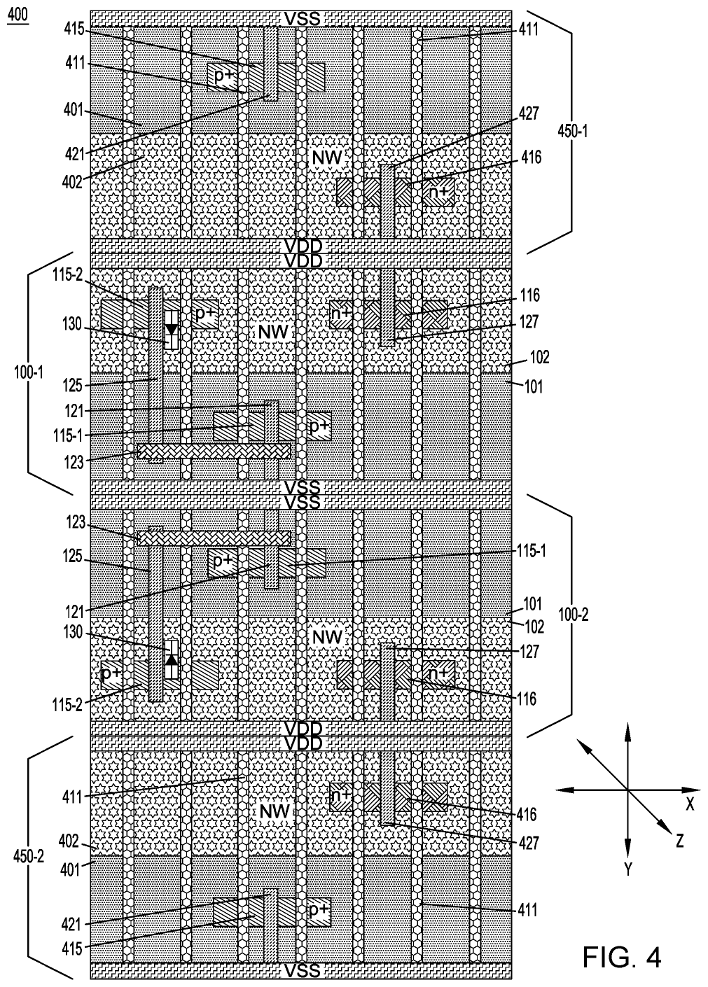

FIG. 4 depicts a schematic top view of a semiconductor structure 400 including multiple well tap cells with p+ diffusion type protection diodes. As can be seen in FIG. 4, the two well tap cells 100-1 and 100-2 in the middle portion of the semiconductor structure 400 comprise the semiconductor structure 100 in a first position and second rotated position. The well tap cell 100-1 comprises the semiconductor structure 100 in the first position, and is the same structure as what is shown in FIG. 1B. The well-tap cell 100-2 comprises the semiconductor structure 100 rotated 180 degrees around the x-axis to the second rotated position.

The upper and lower well-tap cells 450-1 and 450-2 include same p+ and n+ bias structures as the well tap cells 100-1 and 100-2, and do not include the p+ diffusion type protection diodes. In more detail, the upper and lower well-tap cells 450-1 and 450-2 respectively comprise a p-type bias structure comprising a p-type diffusion region 415 formed in a p-type semiconductor substrate 401 between two gate structures including gate conductive portions 411 and connected to a source voltage (VSS) through a first contact line 421. In more detail, the first contact line 421 connects VSS to the p-type diffusion region 415 by contacting a top surface of the p-type diffusion region 415 between the two gate structures. The upper and lower well-tap cells 450-1 and 450-2 also respectively comprise an n-type bias structure comprising an n-type diffusion region 416 formed in an n-well 402 between two gate structures including gate conductive portions 411 and connected to a power voltage (VDD) through a second contact line 427. The second contact line 427 connects VDD to the n-type diffusion region 416 by contacting a top surface of the n-type diffusion region 416 between two gate structures. The upper well tap cell 450-1 is in a first position. The lower well-tap cell 450-2 comprises the same structure as the upper well tap cell 450-1 rotated 180 degrees around the x-axis to a second rotated position.

Referring to FIGS. 5A and 5B, a semiconductor structure 500 includes a p-type semiconductor substrate 501 and an n-well 502 formed in the p-type semiconductor substrate 501. The p-type semiconductor substrate 501 may also be referred to herein as a p-well or p-type portion, and the n-well 502 may also be referred to herein as an n-type portion. The semiconductor structure 500 may also be referred to herein as a filler cell.

The material of the p-type semiconductor substrate 501 and n-well 502 comprises the same semiconductor material as or similar semiconductor material to that of the p-type semiconductor substrates 101/201/301/401 and n-wells 102/202/302/402. In illustrative embodiments, the p-type semiconductor substrate 501 and n-well 502 have the same doping configuration as or a similar doping configuration to that of the p-type semiconductor substrates 101/201/301/401 and n-wells 102/202/302/402.

In illustrative embodiments, gate structures comprising a gate dielectric layer 512 and a gate conductive portion 511 are formed on portions of the p-type semiconductor substrate 501 and n-well 502. The gate structures of the semiconductor structure 500 comprise the same structure as or a similar structure to the gate structures of the p-type semiconductor substrates 101/201/301/401 and n-wells 102/202/302/402.

A p-type (e.g., p+) diffusion region 515 is disposed in the n-well 502 between and/or on lateral sides of the gate structures comprising the gate dielectric layers 512 and the gate conductive portions 511. The gate dielectric layers 512 are formed between bottom surfaces of respective gate conductive portions 511 and top surface portions of the n-well 502. The gate dielectric layers 512 and gate conductive portions 511 include the same materials and configuration as or similar materials and configuration to those of the gate dielectric layers 112/212/312 and the gate conductive portions 111/211/311. In one or more embodiments of the invention, the gate dielectric layers 512 and gate conductive portions 511 can be deposited using the same or similar techniques as those used for the gate dielectric layers 112/212/312 and gate conductive portions 111/211/311.

The p-type diffusion region 515 comprises, for example, a semiconductor material of the n-well 502 doped with p-type dopants at a concentration similar to those noted herein above in connection with the p-type diffusion regions 115/215/315/415. Being a filler cell, the semiconductor structure 500 does not include a bias structure. The p-type diffusion region 515 and protection diode 530 are connected to a source voltage (VSS) through a contact line 521. In more detail, the contact line 521 connects VSS to the p-type diffusion region 515 and the protection diode 530 by contacting a top surface of the p-type diffusion region 515 between the two gate structures. As can be seen in the schematic cross-sectional view of FIG. 5A, the contact line 521 extends perpendicular to a top surface of the n-well 502.

The protection diode 530 comprising the p-type diffusion region 515 is formed in the n-well 502. The protection diode 530 is a p+ diffusion type protection diode. In illustrative embodiments, the protection diode 530 comprises a plasma charge protection diode, and is a reverse bias diode. The protection diode 530 is in a reverse bias configuration when an external voltage applied across the protection diode 530 results in a positive terminal being connected to an n-side of the protection diode 530 and a negative terminal being connected to a p-side of the protection diode 530. A semiconductor device including one or more well tap cells such as those described in connection with FIGS. 1A-4 may further comprise one or more filler cells such as that described in connection with FIGS. 5A and 5B.

In illustrative embodiments, one or more layers of dielectric material are deposited on the semiconductor structure 500 including the gate structures and the p-type diffusion region 515 to form one or more ILD layers. In forming the contact lines 521, a trench corresponding to the contact line 521 is formed in the one or more ILD layers. One or more layers of liner material are deposited to line side and bottom surfaces of the trench with a liner (e.g., diffusion barrier layer and/or seed layer). A layer of metallic material is deposited on the liner to fill remaining portions of the trench for the contact line 521. The surface of the semiconductor structure 500 is planarized down to the upper surface of the one or more ILD layers to remove excess liner and metallic material of the deposited layers, resulting in contact line 521. In one or more embodiments, the liner and metallic fill material may be formed of the same materials as or similar materials to those of the first, second, third and fourth contact lines 121, 123, 125 and 127 of the semiconductor structure 100, the first and second contact lines 221 and 222 of the semiconductor structure 200 and/or the first, second, third and fourth contact lines 321, 323, 325 and 322 of the semiconductor structure 300.

In illustrative embodiments, cells with integrated protection diodes such as those described in FIGS. 1A-5B, may be interchanged with conventional cells in a semiconductor device for increased protection against damage caused by plasma processing. The number of conventional cells that are replaced with the cells with the integrated protection diodes can vary based on a protection to performance degradation ratio. For example, if the level of protection attained by the inclusion of a particular number of the cells with the integrated protection diodes is too small relative to performance degradation that may occur as a result of the number of protection diode cells, then the number of protection diode cells may be capped at or reduced to a certain number for a given semiconductor device. In illustrative embodiments, a threshold protection to performance degradation ratio may be established, such that when the threshold is not met, the number of protection diode cells may be too high, and may need to be reduced until the ratio increases.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs and/or MOSFETs. By way of non-limiting example, the semiconductor devices can include, but are not limited to CMOS and MOSFET devices, and/or semiconductor devices that use CMOS and/or MOSFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface contactions or buried contactions). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

As noted above, the embodiments provide techniques and structures for forming protection diodes and bias structures that introduce current drain paths to reduce current density caused by plasma processing. The illustrative embodiments advantageously provide structures for the reduction of potential to reduce and/or prevent device performance degradation. For example, plasma processing may damage components on a wafer due to the building up of charges on a semiconductor structure caused by active ions that are present during plasma processing. Long interconnect lines, referred to herein as “antennas,” may further increase current density by amplifying current density across gate dielectrics. The area of antennas that are exposed to plasma affects how much charge is collected, with larger areas resulting in more charge collection. The embodiments advantageously reduce current density caused by high antenna ratios (ARs) to prevent component degradation, including that of gate dielectric layers of MOSFETs and/or NVMs, and of insulators of MIM capacitors and other semiconductor devices.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure comprising:
at least one bias structure; and
at least one protection diode, wherein the at least one bias structure is connected to the at least one protection diode through at least one contact line.

2. The semiconductor structure of claim 1, wherein the at least one bias structure is formed in a first portion of a substrate having a first doping type, and the at least one protection diode is formed in a second portion of the substrate having a second doping type opposite the first doping type.

3. The semiconductor structure of claim 2, wherein the at least one protection diode has the first doping type.

4. The semiconductor structure of claim 2, wherein the first doping type is p-type and the at least one bias structure is connected to a source voltage (VSS).

5. The semiconductor structure of claim 4, wherein the at least one protection diode comprises a p-type diffusion region formed in an n-well.

6. The semiconductor structure of claim 2, wherein the first doping type is n-type and the at least one bias structure is connected to a power voltage (VDD).

7. The semiconductor structure of claim 6, wherein the second doping type is p-type and the at least one protection diode comprises an n-type diffusion region formed in the second portion of the substrate having the second doping type.

8. The semiconductor structure of claim 2 further comprising:
at least one other bias structure formed in the second portion of the substrate; and
at least one other protection diode formed in the first portion of the substrate, wherein the at least one other bias structure is connected to the at least one other protection diode through at least one other contact line.

9. The semiconductor structure of claim 1, wherein:
the at least one bias structure and the at least one protection diode are elements of a well tap cell; and
the semiconductor structure further comprises a filler cell comprising at least one other protection diode.

10. A semiconductor structure comprising:
at least one bias structure comprising a first diffusion region having a designated doping type; and
at least one protection diode comprising a second diffusion region having the designated doping type, wherein the at least one bias structure is connected to the at least one protection diode through at least one contact line.

11. The semiconductor structure of claim 10, wherein the first diffusion region is formed in a portion of a substrate having a same doping type as the designated doping type.

12. The semiconductor structure of claim 10, wherein the second diffusion region is formed in a portion of a substrate having a different doping type from the designated doping type.

13. The semiconductor structure of claim 10, wherein the designated doping type is p-type and the at least one bias structure is connected to a source voltage (VSS).

14. The semiconductor structure of claim 10, wherein the designated doping type is n-type and the at least one bias structure is connected to a power voltage (VDD).

15. The semiconductor structure of claim 10, wherein the at least one protection diode is a plasma charge protection diode.

16. A cell comprising:
a substrate comprising a p-type portion and an n-type portion, wherein the n-type portion comprises an n-well;
a p-type bias structure comprising a first p-type diffusion region formed in the p-type portion;
a p-type protection diode comprising a second p-type diffusion region formed in the n-well;
an n-type bias structure comprising a first n-type diffusion region formed in the n-well;
an n-type protection diode comprising a second n-type diffusion region formed in the p-type portion;
wherein the p-type bias structure is connected to the p-type protection diode through a first contact line; and
wherein the n-type bias structure is connected to the n-type protection diode through a second contact line.

17. The cell of claim 16, wherein the p-type bias structure is connected to a source voltage (VSS).

18. The cell of claim 16, wherein the n-type bias structure is connected to a power voltage (VDD).

19. The cell of claim 16, wherein the p-type protection diode and the n-type protection diode are reverse bias diodes.

20. The cell of claim 16, wherein the p-type protection diode and the n-type protection diode are plasma charge protection diodes.
